(19) United States
(12) Patent Application Publication
(10) Pub. No.: US 2026/0332124 A1
(43) Pub. Date: Oct. 22, 2026

(54) PIEZOELECTRIC VIBRATION DEVICE

(71) Applicant: DAISHINKU CORPORATION, Hyogo (JP)

(72) Inventor: Takuya KOJO, Hyogo (JP)

(73) Assignee: DAISHINKU CORPORATION, Hyogo (JP)

(21) Appl. No.: 19/147,443

(22) PCT Filed: Aug. 21, 2023
(86) PCT No.: PCT/JP2023/029988

§ 371 Date: Jul. 11, 2025

(30) Foreign Application Priority Data
Jan. 12, 2023 (JP) 2023-003014

(51) Int. Cl. H03H 9/05; H03H 9/10; H03H 9/19

(52) U.S. Cl. CPC H03H 9/0523; H03H 9/0542; H03H 9/1035; H03H 9/19

(57) ABSTRACT

A piezoelectric vibration device includes at least an oscillator; a molding portion that protects at least the piezoelectric oscillator ; and a substrate including a first mounting surface having a wiring pattern including a plurality of connection terminals on one of principal surfaces thereof, and a second mounting surface having a plurality of external connection terminals. At least the piezoelectric oscillator is connected to the plurality of connection terminals, and the piezoelectric vibration device is covered with the molding portion to include at least the piezoelectric oscillator. The substrate includes, on the second mounting surface side, inspection terminals electrically connected to the connection terminals on which the piezoelectric oscillator is mounted, without going through the external connection terminals.

### TECHNICAL FIELD

The present invention relates to a piezoelectric vibration device.

### BACKGROUND ART

A piezoelectric vibration device includes, for example, a crystal oscillator using a crystal vibration piece. The crystal oscillator includes the crystal vibration piece that is a piezoelectric element, a holding member that holds the crystal vibration piece, and a lid member that seals the holding member. The crystal oscillator is configured such that the crystal vibration piece is held in the holding member having a box shape and formed of an insulator, such as ceramic. The crystal oscillator is configured such that the crystal vibration piece in the holding member is sealed with the lid member in a state where an electrode of the crystal vibration piece and an electrode of the holding member are bonded to each other.

As sizes of various electronic devices have been reduced, there is growing demand to reduce the package size of piezoelectric vibration devices in which the above-described piezoelectric element and an integrated circuit element are mounted on a substrate. Thus, there have been known piezoelectric vibration devices configured such that the above-described piezoelectric oscillator having a laminated structure and the integrated circuit element are mounted on the substrate. For example, a piezoelectric vibration device (electronic component) with a built-in piezoelectric oscillator (piezoelectric component), as described in Patent Document 1, includes: a substrate formed by laminating a first insulator having an external connection terminal (mounting terminal) formed on its lower surface and a second insulator having a wiring electrode that is formed on its upper surface and electrically connected to the external connection terminal; a piezoelectric oscillator disposed on the surface of the second insulator on which the wiring electrode is formed, and electrically connected to the wiring electrode; and a mold resin that encapsulates the piezoelectric oscillator and covers the second insulator.

### CITATION LIST

### Patent Document

Patent Document 1: Japanese Patent Application Publication No. 2017-188825

### SUMMARY OF INVENTION

### Technical Problem

The piezoelectric vibration device described in Patent Document 1 includes a castellation recessed inward of the first insulator on the side of the first insulator. A castellation metal film, which is electrically connected to the external connection terminal, is formed on the castellation. The piezoelectric vibration device has the external connection terminal extended to the side of the first insulator by the castellation metal film. That is, the castellation metal film functions as a part of the external connection terminal. Therefore, when the piezoelectric vibration device is connected to an external substrate terminal by solder, the bonding strength can be improved by the adhesion of solder to the external connection terminal and the castellation metal film.

The castellation metal film located on the side of the first insulator is electrically connected to the piezoelectric oscillator sealed with a mold resin via the external connection terminal. Therefore, the piezoelectric vibration device can measure the characteristics of the mold-sealed piezoelectric oscillator, using the castellation metal film. The characteristics of the piezoelectric oscillator can be measured by bringing a probe of an inspection device into contact with the castellation metal film located on the side of the first insulator. On the other hand, for a piezoelectric vibration device manufactured by a method in which a plurality of piezoelectric vibration devices are mold-sealed in a continuous sheet-like configuration and subsequently severed into individual units, it is difficult to form a castellation metal film on the side of a substrate that is a cut surface. Therefore, for the piezoelectric element device manufactured by the above-described method and which does not have the castellation metal film, it is necessary to remove the mold resin in order to evaluate the characteristics of the mold-sealed piezoelectric oscillator. However, there was a possibility that the characteristics of the above-described piezoelectric oscillator would change due to the removal of the mold resin.

It is an object of the present invention to provide a piezoelectric vibration device that enables the characteristics of a piezoelectric oscillator to be evaluated without removing a mold resin.

### Solution to Problem

The inventor of the present invention has studied a piezoelectric vibration device that enables the characteristics of a piezoelectric oscillator to be evaluated without removing a mold resin. As a result of diligent examination, the inventor has arrived at the following configuration.

A piezoelectric vibration device comprises: at least a piezoelectric oscillator; a resin molding portion that protects at least the piezoelectric oscillator; and a resin substrate including a component mounting surface on one of its principal surfaces and a mounting surface on another one of the principal surfaces that is in parallel with the one of the principal surfaces, the component mounting surface including a wiring pattern that includes a plurality of pads, the mounting surface including a plurality of external connection terminals that are connected to the wiring pattern and to an external substrate. At least the piezoelectric oscillator is mounted on the component mounting surface while being connected to the plurality of pads, and at least a part of the component mounting surface is covered with the resin molding portion to include the piezoelectric oscillator. The resin substrate includes, on the mounting surface side, an inspection terminal electrically connected to one of the pads on which the piezoelectric oscillator is mounted, without going through the external connection terminals.

In the above-described configuration, the piezoelectric vibration device includes, on the mounting surface side of the resin substrate, the inspection terminal electrically connected to one of the pads on which the piezoelectric oscillator is mounted. The inspection terminal is arranged on the mounting surface side, which is not sealed with the resin molding portion, in the resin substrate. Therefore, the piezoelectric vibration device enables the characteristics of the piezoelectric oscillator to be evaluated using the inspection terminal without removing the resin molding portion on the piezoelectric oscillator. In addition, the circuit for evaluating the characteristics of the piezoelectric oscillator is configured with the pad, the inspection terminal, and a circuit wiring that electrically connects the pad and the inspection terminal. Therefore, the measurement results for the characteristics of the piezoelectric oscillator are only affected by parasitic capacitance included in the pad, the inspection terminal, and the circuit wiring that electrically connect the pad and the inspection terminal. That is, the inspection circuit for the piezoelectric oscillator is configured such that the path from the inspection terminal to the piezoelectric oscillator is as simple as possible. This enables the characteristics of the piezoelectric oscillator to be evaluated, while suppressing the influence of parasitic capacitance.

The inspection terminal is arranged on the mounting surface side of the resin substrate. Therefore, the inspection terminal of the piezoelectric vibration device according to the present invention can be provided in a mold-sealed piezoelectric vibration device manufactured by a method in which a plurality of devices are manufactured using a collective substrate and then separated into individual units.

In another aspect, the piezoelectric vibration device according to the present invention may have the following configuration. The inspection terminal is arranged in a position that does not overlap with the pads on which the piezoelectric oscillator is mounted or the plurality of the external connection terminals, when viewed in a direction perpendicular to the mounting surface.

In the above-described configuration, the inspection terminal does not overlap with either the pads on which the piezoelectric oscillator is mounted or the plurality of external connection terminals, when viewed in the direction perpendicular to the mounting surface. That is, the inspection terminal is not directly connected to the pads or the external connection terminals. Therefore, the inspection circuit for the piezoelectric oscillator is configured such that the path from the inspection terminal to the piezoelectric oscillator is simple. The inspection terminal is electrically connected to one of the pads via the circuit wiring. Therefore, the pad is not subject to unevenness or the like caused by the direct connection of inspection terminal to the pad, thereby preventing the occurrence of voids or the like when the piezoelectric oscillator is mounted on the pad. Thus, the connection reliability between the piezoelectric oscillator and the pads can be maintained. Furthermore, the characteristics of the piezoelectric oscillator can be evaluated without removing mold resin, while suppressing the influence of parasitic capacitance.

In another aspect, the piezoelectric vibration device according to the present invention may have the following configuration. The resin substrate is formed of one of glass epoxy resin, polyimide resin, or fluoropolymer resin.

In the above-described configuration, the resin substrate is formed of an insulating material that is easily processed. Therefore, the inspection terminals can be formed in a position that enables the inspection circuit for the piezoelectric oscillator to be configured as simply as possible. In addition, the resin substrate can reduce the difference in thermal expansion coefficient between itself and the mold resin, compared to a substrate formed of a ceramic material, so that it can reduce the influence of stress due to the difference in thermal expansion rate. This enables the characteristics of the piezoelectric oscillator to be evaluated while suppressing the influence of mold sealing.

In another aspect, the piezoelectric vibration device according to the present invention may have the following configuration. The inspection terminal is electrically connected to a conductor filled in a through-hole penetrating the resin substrate in a thickness direction thereof, and the conductor is electrically connected to the piezoelectric oscillator.

In the above-described configuration, the inspection terminal is electrically connected to the conductor filled in the through-hole of the resin substrate. Therefore, the piezoelectric vibration device can secure the conduction from the mounting surface side to the component mounting surface side without the mold resin penetrating into the through-hole.

In addition, the inspection terminal is connected to one of the pads along the shortest path from the component mounting surface to the mounting surface, penetrating the resin substrate in the thickness direction. Thus, the path from the inspection terminal to the piezoelectric oscillator is designed to be simple. This enables the characteristics of the piezoelectric oscillator to be evaluated without removing the mold resin, while suppressing the influence of parasitic capacitance.

In another aspect, the piezoelectric vibration device according to the present invention may have the following configuration. At least the inspection terminal is covered with an insulating resin.

In the above-described configuration, even when the resin substrate comes into contact with the external substrate or the like, the inspection terminal covered with the insulating resin is not electrically connected to the external substrate or the like. Therefore, the piezoelectric vibration device can prevent variation in the characteristics of the piezoelectric oscillator due to the contact between the inspection terminal and the external substrate or the like. On the other hand, the insulating resin covering the inspection terminal can be removed more easily than the mold resin. This enables the characteristics of the piezoelectric oscillator to be evaluated without removing the mold resin, when it is required to evaluate the characteristics of the piezoelectric oscillator.

In another aspect, the piezoelectric vibration device according to the present invention may have the following configuration. The resin substrate is configured such that at least a part of the mounting surface is covered with the insulating resin.

In the above-described configuration, at least a part of the mounting surface of the resin substrate, including the inspection terminal, is covered with the insulating resin. Therefore, even when the resin substrate comes into contact with the external substrate or the like, the inspection terminal is not electrically connected to the external substrate or the like. In addition, terminals other than the inspection terminal, the wiring circuits, the external connection terminals, or the like on the mounting surface are protected by the insulating resin. Therefore, the piezoelectric vibration device can prevent the inspection terminal, the terminals other than the inspection terminal or the like, from being in contact with the external substrate or the like. On the other hand, the insulating resin covering the inspection terminal can be removed more easily than the mold resin. Thus, when it is required to measure the characteristics of the piezoelectric oscillator, the insulating resin can be removed to expose the inspection terminal. This enables the characteristics of the piezoelectric oscillator to be evaluated without removing the mold resin.

### Advantageous Effects of Invention

According to one embodiment of the present invention, it is possible to evaluate the characteristics of the piezoelectric oscillator without removing the mold resin.

### BRIEF DESCRIPTION OF DRAWINGS

FIG. 1 is a plan view of a piezoelectric vibration device according to a first embodiment of the present invention.

FIG. 2 is a side view of an oscillator in the piezoelectric vibration device according to the first embodiment of the present invention.

FIG. 3 is a cross-sectional view as seen in a direction indicated by arrow B in FIG. 2.

FIG. 4 is a bottom view of the oscillator in the piezoelectric vibration device according to the first embodiment of the present invention.

FIG. 5 is a cross-sectional view of the piezoelectric vibration device sealed with a mold resin according to the first embodiment of the present invention, as seen in a direction indicated by arrow A in FIG. 1.

FIG. 6 is a plan view illustrating a first mounting surface, which is a component mounting surface of a resin substrate in the piezoelectric vibration device according to the first embodiment of the present invention.

FIG. 7 is a plan view of a piezoelectric vibration device according to a variation of the first embodiment of the present invention.

FIG. 8 is a transparent plan view of a second mounting surface, which is a mounting surface of the resin substrate in the piezoelectric vibration device according to the first embodiment of the present invention, as seen from the first mounting surface side.

FIG. 9 is a cross-sectional view as seen in a direction indicated by arrow C in FIG. 6.

FIG. 10 is a plan view illustrating the piezoelectric vibration device according to the first embodiment of the present invention, in which a part of an insulating resin on the second mounting surface of the resin substrate has been removed.

FIG. 11 is a plan view of a piezoelectric vibration device according to a second embodiment of the present invention.

FIG. 12 is a longitudinal cross-sectional view of an oscillator in the piezoelectric vibration device according to the second embodiment 2 of the present invention.

FIG. 13 is a plan view illustrating a first mounting surface of a resin substrate in the piezoelectric vibration device according to the second embodiment of the present invention.

FIG. 14 s a transparent plan view of a second mounting surface of the resin substrate in the piezoelectric vibration device according to the second embodiment of the present invention, as seen from the first mounting surface side.

FIG. 15 is a cross-sectional view as seen in a direction indicated by arrow D in FIG. 14.

### DESCRIPTION OF EMBODIMENT

Embodiments will be described hereinafter with reference to the drawings. In the drawings, the same parts are denoted by the same reference numerals, and description thereof will not be repeated. The dimensions of components in the drawings do not strictly represent actual dimensions of the components and dimensional proportions of the components. In the embodiments below, the term “principal surface” refers to a surface having a largest area in a target member or a surface having a largest area when viewed in a thickness direction in a plate member.

In the following description of a piezoelectric vibration device 1, which is an embodiment of the present invention, a longitudinal direction of oscillators 2 and 22 and substrates 11 and h is an “X-direction,” a short direction thereof is a “Y-direction, and a direction that is an opening direction of a frame portion 24 in the oscillator 22 and is orthogonal to the X-direction and the Y-direction, as well as a direction perpendicular to a principal surface in the substrates 11 and 31, is a “Z-direction.” In the embodiments, the X-direction and the Y-direction are directions in a horizontal plane. The Z-direction is the vertical direction. However, these definitions of the directions are not intended to limit orientations of the piezoelectric vibration device 1 when it is used.

In the description below, the expression “fixed,” “connected,” “bonded,” “attached,” or the like (hereinafter collectively referred to as “fixed or the like”) encompasses not only a case where members are directly fixed or the like to each other, but also a case where members are fixed or the like to each other via some other member. That is, in the description below, the expression “fixed or the like” encompasses a meaning that members are directly and indirectly fixed or the like to each other.

### First Embodiment

### (Configuration of Piezoelectric Vibration Device 1)

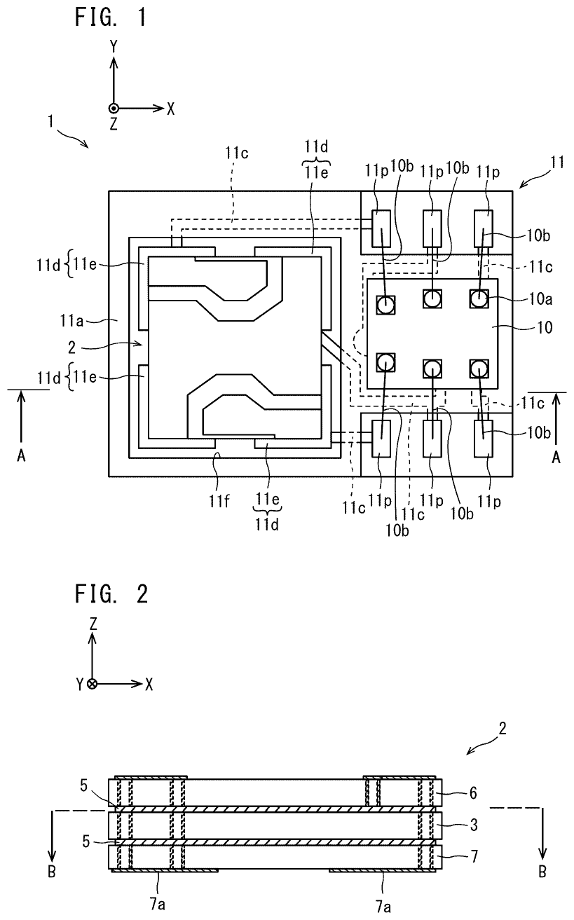

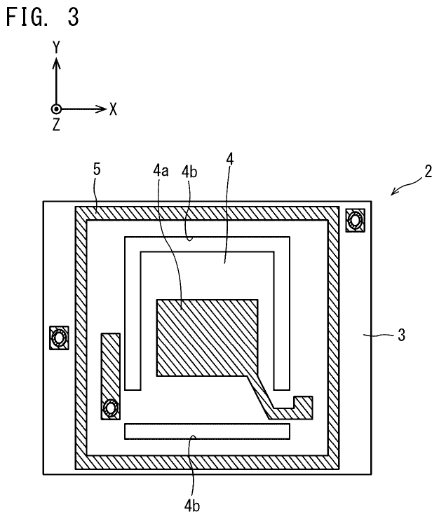

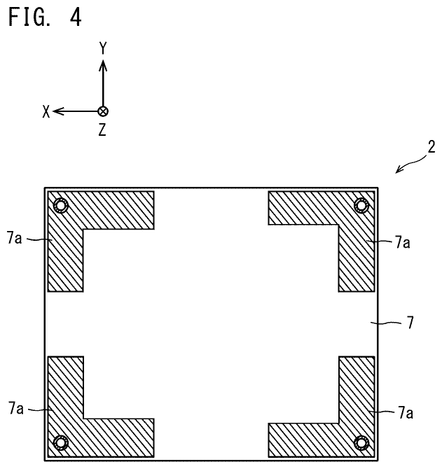

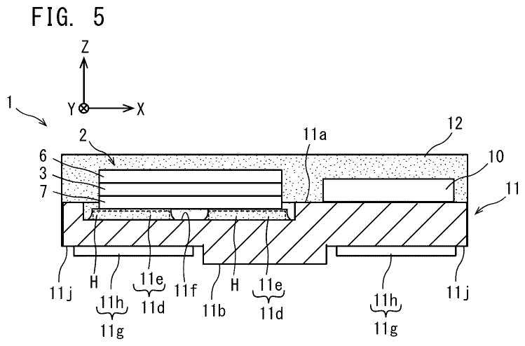

With reference to FIGS. 1 to 5, a piezoelectric vibration device 1, which is the first embodiment of a piezoelectric vibration device of the present invention, will now be described. FIG. 1 is a plan view of the piezoelectric vibration device 1 according to the first embodiment of the present invention. FIG. 2 is a side view of an oscillator 2 in the piezoelectric vibration device 1. FIG. 3 is a cross-sectional view as seen in a direction indicated by arrow B in FIG. 2. FIG. 4 is a bottom view of the oscillator 2 in the piezoelectric vibration device 1. FIG. 5 is a cross-sectional view of the piezoelectric vibration device 1 sealed with a mold resin, as seen in a direction indicated by arrow A in FIG. 1.

As illustrated in FIG. 1, the piezoelectric vibration device 1 includes the oscillator 2, an integrated circuit element 10, a substrate 11, and a molding portion 12 (see FIG. 5).

As illustrated in FIG. 2 to FIG. 4, the oscillator 2 is a piezoelectric oscillator with a piezoelectric body that converts an applied force to a voltage or converts an applied voltage to a force. The oscillator 2 includes a piezoelectric vibration plate 3, a first sealing member 6, and a second sealing member 7. The oscillator 2 has a sandwich structure in which the piezoelectric vibration plate 3 is disposed between the first sealing member 6 and the second searing member 7.

As illustrated in FIG. 3, the piezoelectric vibration plate 3 is a rectangular plate member formed of crystal that is a piezoelectric material. The piezoelectric vibration plate 3 has two principal surfaces, each of which is provided with one of a pair of excitation electrodes 4a. The piezoelectric vibration plate 3 includes a notch portion 4b that penetrates from one of the principal surfaces to the other one of the principal surfaces such that the notch portion 4b surrounds the pair of excitation electrodes 4a with portions of the excitation electrodes 4a left non-surrounded. Thus, a portion, in which the pair of excitation electrodes 4a is arranged, is configured as a vibrating portion 4 having a cantilever structure that can vibrate in the Z-direction. The piezoelectric vibration plate 3 includes, on both of the principal surfaces thereof, bonding materials 5 bonded to the first sealing member 6 and the second sealing member 7 such that the bonding materials 5 surround the vibrating portion 4.

As illustrated in FIG. 2, the first sealing member 6 and the second sealing member 7 seal the vibrating portion 4 of the piezoelectric vibration plate 3. The first sealing member 6 and the second sealing member 7 are each a rectangular plate member formed of the same crystal as the piezoelectric vibration plate 3. The first sealing member 6 and the second sealing member 7 each have a shape that can entirely cover one of the principal surfaces of the piezoelectric vibration plate 3 when one principal surface of each of the first sealing member 6 and the second sealing member 7 is arranged to face a corresponding one of the principal surfaces of the piezoelectric vibration plate 3. Each of the first sealing member 6 and the second sealing member 7 includes, on one of the principal surfaces thereof, the bonding material 5 that is bonded to the bonding material 5 of the piezoelectric vibration plate 3.

One of the principal surfaces of the piezoelectric vibration plate 3 is covered by the first sealing member 6. The other one of the principal surfaces of the piezoelectric vibration plate 3 is covered by the second sealing member 7. At this time, the bonding materials 5 of the piezoelectric vibration plate 3 and the bonding material 5 of each of the first sealing member 6 and the second sealing member 7 are diffusion-bonded. Thus, the vibrating portion 4 of the piezoelectric vibration plate 3 is hermetically sealed with the first sealing member 6 and the second sealing member 7.

As illustrated in FIG. 4, the second sealing member 7 includes, on the other one of the principal surfaces thereof, four oscillator mounting terminals 7a electrically connected to electrodes of the substrate 11. Each of the four oscillator mounting terminals 7a is a plate-shaped terminal formed of conductive metal. Each of the four oscillator mounting terminals 7a is arranged at one of four corners of the rectangle.

The oscillator 2, configured as described above, is a package having a three-layer structure in which both of the principal surfaces of the piezoelectric vibration plate 3 are sealed by the first sealing member 6 and the second sealing member 7, respectively. In addition, by covering both of the principal surfaces of the piezoelectric vibration plate 3 by the first sealing member 6 and the second sealing member 7, an internal space, which accommodates the vibrating portion 4 included in the piezoelectric vibration plate 3, is formed. That is, in the oscillator 2, the vibrating portion 4 including the pair of excitation electrodes 4a is hermetically sealed in the internal space of this package. An inert gas, such as nitrogen gas, is sealed within the internal space. The oscillator 2 oscillates at a predetermined frequency in response to an applied voltage.

As illustrated in FIG. 1, the integrated circuit element 10 is an IC that controls the oscillator 2. The integrated circuit element 10 includes an electronic circuit, such as an oscillation circuit that is connected to a thermosensitive element (thermistor) for detecting a surrounding temperature state and generates a predetermined oscillation output, or the like. The integrated circuit element 10 outputs the oscillation output generated by the oscillation circuit as a reference signal, such as a clock signal, to outside via integrated circuit element mounting terminals 10a. A portion of the integrated circuit element 10 except the integrated circuit element mounting terminals 10a is covered by resin.

The substrate 11 is a resin substrate that electrically connects the oscillator 2 and the integrated circuit element 10 to each other via a wiring pattern and forms the oscillator 2 and the integrated circuit element 10 as an integrated body. For example, the substrate 11 is formed of one of glass epoxy resin, polyimide resin, or fluoropolymer resin. The substrate 11 is a single-layer substrate. One of a pair of principal surfaces of the substrate 11 is configured as a first mounting surface 11a that includes four connection terminals 11d and the wiring pattern including pads, lands, or the like, which are formed by a conductor, such as copper. The four connection terminals 11d are electrically connected to the wiring pattern including the plurality of pads on the first mounting surface 11a via internal wirings 11c. Each of the internal wirings 11c is at least partially covered with an insulating resin. Thus, the single-layer substrate 11 has only the first mounting surface 11a and a second mounting surface 11b, which enables a simple configuration of the internal wirings 11c.

The oscillator 2 and the integrated circuit element 10 are each mounted on the first mounting surface 11a of the substrate 11. The oscillator 2 is arranged on the substrate 11 such that the second sealing member 7 (see FIG. 2) faces the first mounting surface 11a. Each of the four oscillator mounting terminals 7a of the second sealing member 7 (see FIG. 4) is electrically connected to a corresponding one of the four connection terminals 11d on the first mounting surface 11a by conductive solder H. Similarly, each of the integrated circuit element mounting terminals 10a of the integrated circuit element 10 is electrically connected to the wiring pattern on the first mounting surface 11a via a wire 10b and a wire connection terminal 11p that functions as a wire connection pad on the first mounting surface 11a. In this manner, the oscillator 2 and the integrated circuit element 10 are arranged side by side on the first mounting surface 31a of the substrate 11.

As illustrated in FIG. 5, the other one of the principal surfaces of the substrate 11 that extends in parallel to the one of the principal surfaces is configured as the second mounting surface 11b that includes external connection terminals 11g provided for mounting the substrate 11 on an external substrate, which is not illustrated. Each of the external connection terminals 11g is a plate-shaped terminal formed of conductive metal. The external connection terminals 11g are electrically connected to the wiring pattern on the first mounting surface 11a including the plurality of pads via the internal wirings 11c (not illustrated).

The substrate 11 is configured such that the oscillator 2 and the integrated circuit element 10 mounted on the first mounting surface 11a are electrically connectable to the unillustrated external substrate via the unillustrated wiring pattern on the first mounting surface 11a, the internal wirings 11c, and the external connection terminals 11g on the second mounting surface 11b. This enables the oscillator 2 to oscillate at a predetermined frequency in response to a voltage applied from the external substrate.

As illustrated in FIG. 5, the molding portion 12, which is a resin molding portion, protects the substrate 11 and at least the oscillator 2 of the oscillator 2 and the integrated circuit element 10 mounted on the substrate 11. The molding portion 12 is a thermosetting resin, such as epoxy resin. The molding portion 12 covers the substrate 11 and at least a portion of the oscillator 2 of the oscillator 2 and the integrated circuit element 10 mounted on the substrate 11 with the epoxy resin cured by heat. In this embodiment, the molding portion 12 covers the first mounting surface 11a of the substrate 11, as well as the oscillator 2 and the integrated circuit element 10 mounted on the first mounting surface 11a of the substrate 11. On the other hand, the second mounting surface 11b of the substrate 11 is not sealed with the molding portion 12.

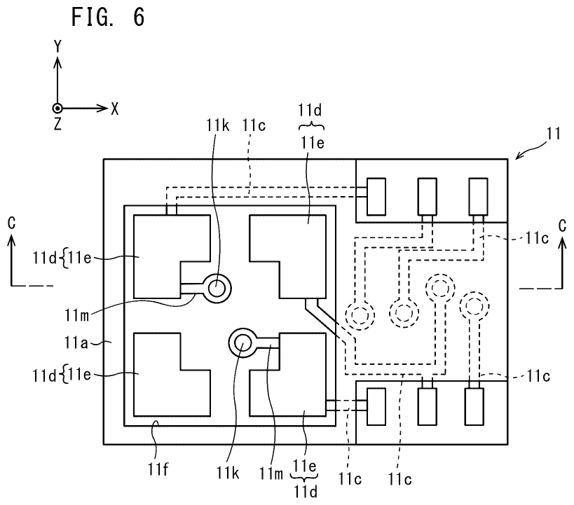

With reference to FIG. 6, the first mounting surface 11a and the connection terminals 11d of the substrate 11 will now be described in detail. FIG. 6 is a plan view illustrating the first mounting surface 11a, which is a component mounting surface of the substrate 11 in the piezoelectric vibration device 1.

As illustrated in FIG. 6, the first mounting surface 11a of the substrate 11 is the one of the principal surfaces thereof, which is electrically connected to the oscillator 2 and the integrated circuit element 10. The first mounting surface 11a includes a recessed portion 11f. The recessed portion 11f is a rectangular recess extending in the X direction and the Y direction, when viewed in the Z direction. The recessed portion 11f has a shape with which the oscillator mounting terminals 7a of the oscillator 2 (see FIG. 2) can be arranged therein.

In the recessed portion 11f, the connection terminals 11d each having an approximately L shape are arranged. That is, the substrate 11 includes the four connection terminals 11d. Each of the connection terminals 11d is a plate-shaped terminal formed of conductive metal.

Each of the connection terminals 11d protrudes from the bottom surface of the recessed portion 11f in the Z-direction. A principal surface of each of the four connection terminals 11d (hereinafter simply referred to as the “connection terminals 11d”) is configured as a bonding surface 11e bonded to a corresponding one of the four oscillator mounting terminals 7a of the oscillator 2. The bonding surfaces 11e are positioned below the first mounting surface 11a, toward the second mounting surface 11b. That is, the bonding surfaces 11e are recessed relative to the first mounting surface 11a. The bonding surfaces lle are not covered by an insulating base material of the substrate 11 and are exposed.

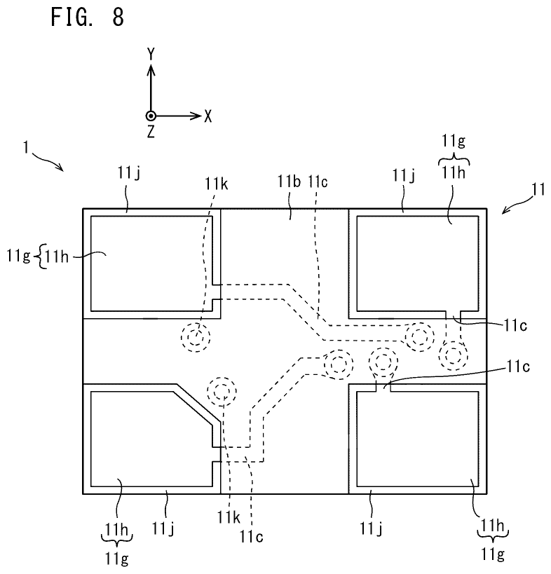

The internal wirings 11c are connected to the connection terminals 11d. The internal wirings 11c are formed of conductive metal. The internal wirings 11c electrically connect the wiring pattern on the first mounting surface 11a to the external connection terminals 11g (see FIG. 8). An internal wiring 11c is connected to a corresponding one of the connection terminals 11d within the recessed portion 11f.

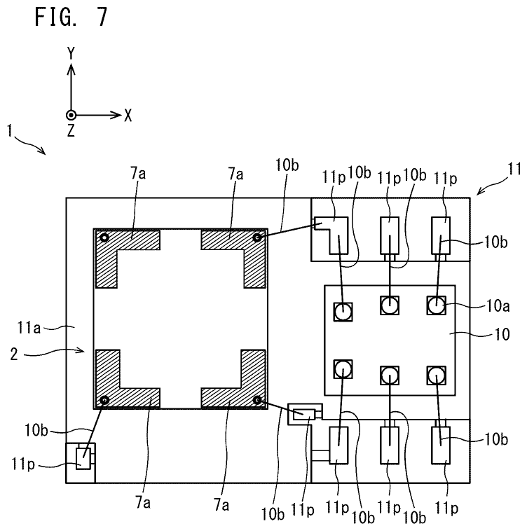

FIG. 7 is a plan view of a variation of the piezoelectric vibration device 1. As illustrated in FIG. 7, the piezoelectric vibration device 1 may be configured such that an oscillator mounting terminal 7a of the oscillator 2 is connected to a corresponding wire connection terminal 11p on the first mounting surface 11a with a wire 10b. The oscillator 2 is arranged on the first mounting surface 11a of the substrate 11 such that the oscillator mounting terminals 7a are visible when the first mounting surface 11a is viewed in the Z direction. An oscillator mounting terminal 7a is electrically connected to the wiring pattern on the first mounting surface 11a via a corresponding wire 10b and wire connection terminal 11p on the first mounting surface 11a. In this manner, the oscillator 2 and the integrated circuit element 10 may not only be configured to be electrically connected to the wiring pattern on the substrate 11 using solder, bonding material, adhesive, or the like, but also configured to be electrically connected to the wiring pattern on the substrate 11 using the wires 10b. A metal bump may also be used as a bonding material.

With reference to FIG. 8, the second mounting surface 11b and the external connection terminals 11g of the substrate 11 will now be described in detail. FIG. 8 is a plan view of the second mounting surface 11b, which is a mounting surface of the substrate 11 in the piezoelectric vibration device 1.

As illustrated in FIG. 8, the second mounting surface 11b is the other one of the principal surfaces of the substrate 11 and is electrically connected to the unillustrated external substrate. The second mounting surface 11b includes the four external connection terminals 11g at the four corners. The second mounting surface 11b also includes four recessed portions 11j corresponding to the four external connection terminals 11g. Each of the four recessed portions 11j is a stepped portion in which an arbitrarily defined range is recessed in a direction perpendicular to the second mounting surface 11b. Each of the four recessed portions 11j is arranged at a corresponding one of the four corners, each including a vertex that is an intersection between a long side and a short side of the substrate 11 when viewed in the Z-direction. As for each of the four recessed portions 11j, a range including respective portions of the long side and the short side each extending from the vertex and being an outer edge of the substrate 11 is recessed. Each of the recessed portions 11j has a shape with which a mounting terminal on the external substrate can be arranged therein.

For each of the external connection terminals 11g, a principal surface thereof is configured as a terminal that is connected to a connection terminal of the external substrate. The four external connection terminals 11g (hereinafter simply referred to as the “external connection terminals 11g”) are plate-shaped, approximately rectangular terminals formed of conductive metal. Each of the external connection terminals 11g is arranged in a corresponding one of the four recessed portions 11j. The external connection terminals 11g are approximately rectangular in shape. Each of the external connection terminals 11g includes, on the principal surface thereof, a bonding surface 11h bonding to a corresponding one of the connection terminals of the external substrate. The bonding surfaces 11h are not covered by the insulating base material of the substrate 11 and are exposed. The bonding surfaces 11h are positioned below the second mounting surface 11b, toward the first mounting surface 11a. That is, the bonding surfaces 11h are recessed relative to the first mounting surface 11a.

The internal wirings 11c are connected to the external connection terminals 11g. The internal wirings 11c run inside the substrate 11 and are arranged in the recessed portions 11j. The external connection terminals 11g are bonded to the connection terminals of the external substrate that is not illustrated, by solder or the like.

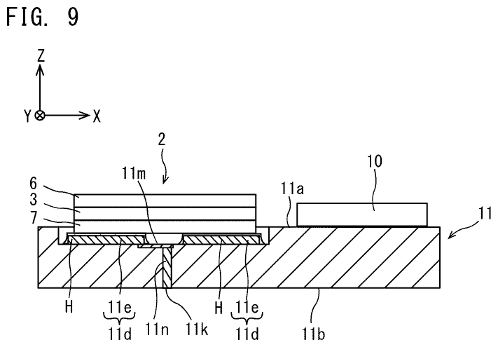

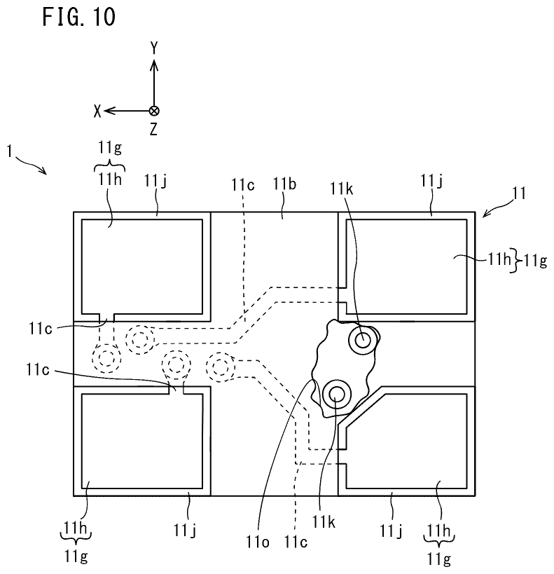

With reference to FIGS. 6 and 8 to 10, an inspection terminal on the substrate 11 will now be described. FIG. 9 is a cross-sectional view as seen in a direction indicated by arrow C in FIG. 6. FIG. 10 is a plan view illustrating the piezoelectric vibration device 1, in which a part of an insulating resin on the second mounting surface 11b of the substrate 11 has been removed.

As illustrated FIGS. 6 and 8 to 10, the inspection terminal 11k is used to evaluate the characteristics of the oscillator 2 mounted on the first mounting surface 11a of the substrate 11. The piezoelectric vibration device 1 is provided with a pair of inspection terminals 11k, each corresponding to one of the two electrodes of the oscillator 2. In the following embodiment, the inspection terminals 11k refer to the pair of inspection terminals 11k unless otherwise described.

The pair of inspection terminals 11k (hereinafter simply referred to as “inspection terminals 11k”) is electrically connected, via a wiring circuit or the like, to the connection terminals 11d on the first mounting surface 11a to which the oscillator 2 is electrically connected. The inspection terminals 11k are located closer to the second mounting surface 11b. In this embodiment, the inspection terminals 11k are located substantially in the same plane as the second mounting surface 11b. Each of the inspection terminals 11k is electrically connected to an end portion of a conductor 11n (see FIG. 9), located on the second mounting surface 11b side, within a corresponding through-hole, wherein the conductor 11n covers at least the inner surface of the through-hole extending through the substrate 11 from the first mounting surface 11a side toward the second mounting surface 11b side. In this embodiment, each of the inspection terminals 11k is integrally formed with a corresponding conductor 11n filled in the through-hole. The conductors 11n are preferably of the same type as the connection terminals 11d.

In addition, at both end portions of each through-hole, lands are arranged, each of which is an annular conductor with an outer diameter larger than the inner diameter of the through-hole. Each of the inspection terminals 11k is electrically connected to the lands. The inspection terminals 11k, as configured in this manner, have a smaller area than the connection terminals 11d or the like, when viewed perpendicularly to the first mounting surface 11a of the substrate 11, which enables improved flexibility in arrangement, and space savings on the substrate 11.

As illustrated in FIG. 6, the inspection terminals 11k are arranged within an area surrounded by the four connection terminals 11d, which are pads on which the oscillator 2 is mounted. In this state, the inspection terminals 11k are arranged in positions that do not overlap with the connection terminals 11d, when viewed in the direction perpendicular to the first mounting surface 11 a. That is, each of the conductors 11n electrically connected to a corresponding one of the inspection terminals 11k has an end portion on the first mounting surface 11a side, which is not directly connected to the connection terminal 11d.

As illustrated in FIG. 8, the inspection terminals 11k are arranged within an area surrounded by the external connection terminals 11g. In this state, the inspection terminals 11k are arranged in positions that do not overlap with the external connection terminals 11g, when viewed in the direction perpendicular to the first mounting surface 11a. That is, the inspection terminals 11k are not directly connected to the external connection terminals 11g. Naturally, the conductors 11n electrically connected to the inspection terminals 11k are not directly connected to the connection terminals 11d or the external connection terminals 11g.

As illustrated in FIGS. 6 and 9, each of the conductors 11n, to which a corresponding one of the pair of inspection terminals 11k is connected, has the end portion on the first mounting surface 11a side, which is located substantially in the same plane as the first mounting surface 11a. The end portions of the conductors 11n on the first mounting surface 11a side are each electrically connected to one end portion of a different internal wiring 11m. The other end portion of each of the internal wirings 11m is electrically connected to one of the connection terminals 11d. That is, the end portion of each of the conductors 11n on the first mounting surface 11a side is electrically connected to one of the connection terminals 11d via the internal wiring 11m. The inspection terminals 11k and the internal wirings 11m are covered with an insulating resin.

The inspection terminals 11k are located substantially in the same plane as the second mounting surface 11b. The conductors 11n, to which the inspection terminals 11k are connected, have the end portions on the first mounting surface 11a side, which are connected to corresponding connection terminals 11d, internal wirings, or the like. That is, each of the pair of inspection terminals 11k is electrically connected to a corresponding connection terminal 11d on the first mounting surface 11a side without going through an external connection terminal 11g on the second mounting surface 11b side.

As illustrated in FIG. 8, on the second mounting surface 11b, at least the inspection terminals 11k are covered with an insulating resin. Furthermore, in the substrate 11, at least a part of the second mounting surface 11b is covered with the insulating resin. That is, the inspection terminals 11k and at least a part of the second mounting surface 11b are covered with the insulating resin. The insulating resin is a resin that is removable from the inspection terminals 11k by physical or scientific methods. The insulating resin covering the inspection terminals 11k has a thickness such that the inspection terminal 11k are visible through the insulating resin from the outside. Therefore, the piezoelectric vibration device 1 is configured such that the positions of the inspection terminals 11k covered by the insulating resin can be identified from above the insulating resin. Accordingly, the piezoelectric vibration device 1 enables the resin removal positions to be readily identified in order to expose the ends of the inspection terminals 11k.

The inspection terminals 11k are electrically connected to the oscillator 2 via the conductors 11n, the internal wirings 11m and the connection terminals 11d. The inspection terminals 11k are located on the second mounting surface 11b side that is not sealed with the molding portion 12 (see FIG. 5). Therefore, the inspection terminals 11k can be electrically connected to the oscillator 2 sealed with the molding portion 12, via their ends on the second mounting surface 11b side.

The piezoelectric vibration device 1 with the inspection terminals 11k, as described above, is configured to be electrically connectable to the external substrate with the oscillator 2 and the integrated circuit element 10 sealed with the molding portion 12. In this state, even when the second mounting surface 11b of the substrate 11 comes into contact with the external substrate, the inspection terminals 11k located on the second mounting surface 11b side are covered with the insulating resin, so that electrical connection to the external substrate is prevented. In addition, terminals other than the inspection terminals 11k, wiring circuits, the external connection terminals, or the like, on the second mounting surface 11b of the substrate 11 are protected by the insulating resin. Therefore, the piezoelectric vibration device 1 can prevent the inspection terminals 11k, the terminals other than the inspection terminals 11k, or the like, from being in contact with the external substrate or the like. On the other hand, the piezoelectric vibration device 1 is configured such that the inspection terminals 11k are visible through the insulating resin. Therefore, the piezoelectric vibration device 1 allows the insulating resin covering the inspection terminals 11k to easily be removed in order to expose the inspection terminals 11k.

As illustrated in FIG. 10, when measuring the characteristics of the oscillator 2 sealed with the molding portion 12 in the piezoelectric vibration device 1, the insulating resin of an insulating area 110, covering the inspection terminals 11k, is removed. The piezoelectric vibration device 1 causes probes of an inspection device or the like, which is not illustrated, to be brought into contact with each of the pair of inspection terminals 11k exposed on the second mounting surface 11b side of the substrate 11. The oscillator 2 is electrically connected to the inspection device via the pair of inspection terminals 11k, the conductors 11n and the internal wirings 11m. The characteristics of the oscillator 2 are measured in accordance with a predetermined procedure.

The piezoelectric vibration device 1, as configured in this manner, includes the inspection terminals 11k that are electrically connectable to the oscillator 2 on the first mounting surface 11a side of the substrate 11. The inspection terminals 11k are located on the second mounting surface 11b side, which is not sealed with the molding portion 12, in the substrate 11. Therefore, in the piezoelectric vibration device 1, the characteristics of the oscillator 2 can be evaluated using the inspection terminals 11k without removing the resin mold on the oscillator 2.

An inspection circuit for the oscillator 2 is configured with the connection terminals 11d, the inspection terminals 11k, as well as the conductors 11n and the internal wirings 11m that electrically connect the connection terminals 11d and the inspection terminals 11k, so as to be as short and simple as possible. Thus, the measurement results of the oscillator 2 are only affected by parasitic capacitance included in the connection terminals 11d, the inspection terminals 11k, as well as the conductors 11n and the internal wirings 11m that electrically connect the connection terminals 11d and the inspection terminals 11k.

The inspection terminals 11k are electrically connected to the connection terminals 11d via the internal wirings 11m. Therefore, the connection terminals 11d are not subject to unevenness or the like caused by the direct connection of inspection terminals 11k, which are conductors filled in the through-holes of the substrate 11, to the connection terminals 11d, thereby preventing the occurrence of voids or the like when the oscillator 2 is mounted on the connection terminals 11d. Thus, even with the inspection terminals 11k provided, the connection reliability between the oscillator 2 and the connection terminals 11d is not impaired.

The inspection terminals 11k are electrically connected to the conductors 11n filled in the through-holes formed in the substrate 11. Therefore, the piezoelectric vibration device 1 can secure the conduction from the first mounting surface 11a side to the second mounting surface 11b without the mold resin penetrating into the through-holes. In addition, the inspection terminals 11k are connected to the connection terminals 11d along the shortest path penetrating the substrate 11 in the thickness direction. Thus, the path from each inspection terminal 11k to the oscillator 2 is designed to be simple.

This enables the characteristics of the oscillator 2 to be evaluated without removing the mold resin, while suppressing the influence of parasitic capacitance.

The substrate 11 is formed of an insulating material that is easily processed, such as glass epoxy resin, polyimide resin, and fluoropolymer resin. Therefore, the inspection terminals 11k can be formed in positions that enables the inspection circuit for the oscillator 2 to be configured as simply as possible. In addition, the substrate 11 can reduce the difference in thermal expansion coefficient between itself and the mold resin, compared to a substrate made of ceramic material, so that it can reduce the influence of stress due to the difference in expansion rate.

### Second Embodiment

### <Configuration of Piezoelectric Vibration Device 21>

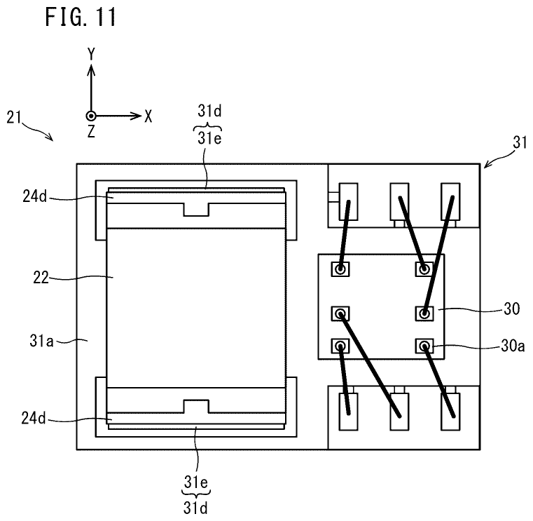

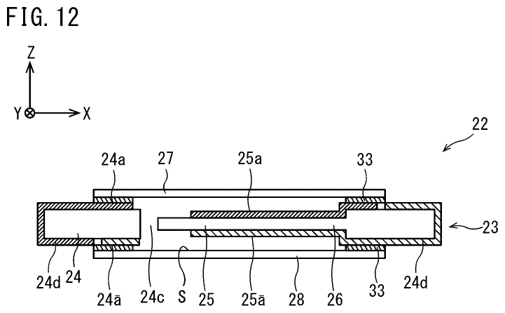

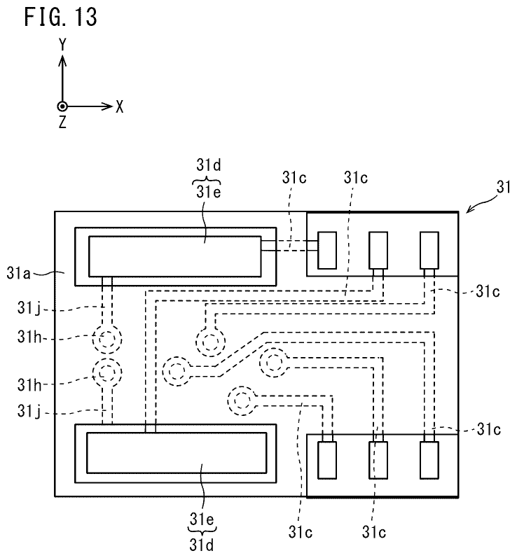

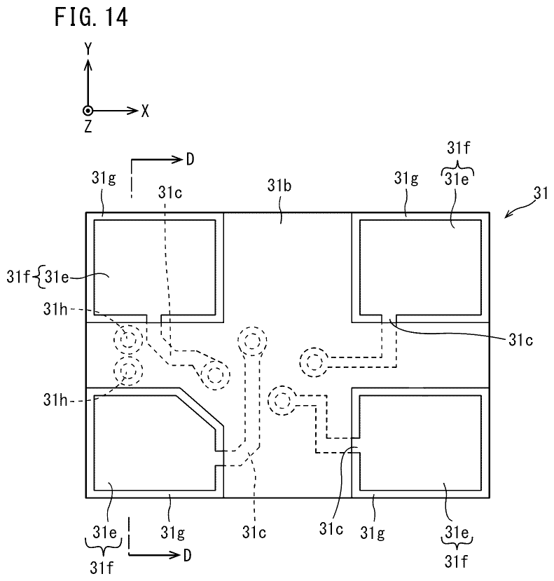

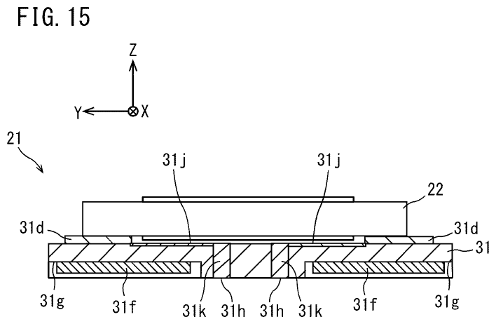

With reference to FIGS. 11 to 14, a piezoelectric vibration device 21, which is the second embodiment of a piezoelectric vibration device of the present invention, will now be described. FIG. 11 is a plan view of the piezoelectric vibration device 21 according to the second embodiment of the present invention. FIG. 12 is a longitudinal cross-sectional view of an oscillator 22 in the piezoelectric vibration device 21. FIG. 13 is a plan view illustrating a first mounting surface of a substrate 31 in the piezoelectric vibration device 21. FIG. 14 is a plan view illustrating a second mounting surface of the substrate 31 in the piezoelectric vibration device 21. FIG. 15 is a cross-sectional view as seen in a direction indicated by arrow D in FIG. 14. Note that, in the following embodiment, specific description of points similar to those in the embodiment already described will be omitted and only a portion which differs from the already described embodiment will be described in detail.

As illustrated in FIG. 11, the piezoelectric vibration device 21 includes the oscillator 22, an integrated circuit element 30, the substrate 31, and the molding portion 12 (see FIG. 5).

As illustrated in FIG. 12, the oscillator 22 is a piezoelectric oscillator with a piezoelectric body that converts an applied force to a voltage or converts an applied voltage to a force. The oscillator 22 includes a piezoelectric vibration plate 23, a first sealing member 27, and a second sealing member 28.

The piezoelectric vibration plate 23 is a rectangular crystal vibrating piece that is crystal cut out in a specific direction. The piezoelectric vibration plate 23 includes a frame portion 24, a vibrating portion 25, and a connecting portion 26. In the piezoelectric vibration plate 23, the frame portion 24, the vibrating portion 25, and the connecting portion 26 are formed as one body. That is, the frame portion 24, the vibrating portion 25, and the connecting portion 26 are formed as a single member.

The frame portion 24 surrounds the vibrating portion 25. The frame portion 24 is formed of a rectangular plate material in a plan view that is a view in the Z-direction. The frame portion 24 is a frame member that includes a pair of principal surfaces each having a rectangular opening when viewed in the Z-direction. That is, the frame portion 24 includes a rectangular through-hole 24c that penetrates from one of the principal surfaces to the other one of the principal surfaces.

The vibrating portion 25 is a piezoelectric body. The vibrating portion 25 is a plate material having an approximately rectangular shape in a plan view that is a view in a direction perpendicular to a pair of principal surfaces thereof each having a largest area. The vibrating portion 25 is arranged inside the frame portion 24. A portion of the vibrating portion 25 is connected to the frame portion 24 via the connecting portion 26 having a plate shape. The vibrating portion 25 is held in a cantilever-supported state on the frame portion 24 via the connecting portion 26. The vibrating portion 25 includes a pair of excitation electrodes 25a. The pair of excitation electrodes 25a is connected to oscillator mounting terminals 24d.

The first sealing member 27 and the second sealing member 28 are sealing members that seal the inside of the frame portion 24. The first sealing member 27 and the second sealing member 28 are rectangular members when viewed in the Z-direction. The first sealing member 27 and the second sealing member 28 are made of metal, for example. The first sealing member 27 and the second sealing member 28 are smaller than the frame portion 24 and larger than the opening of the frame portion 24. The first sealing member 27 and the second sealing member 28 are each bonded to a bonding surface 24a of a corresponding principal surface of the frame portion 24, using a bonding material 33 that is a thermoplastic adhesive. The first sealing member 27 and the second sealing member 28 cover the opening of the frame portion 24.

The oscillator 22, configured in the above-described manner, has a three-layer structure including the piezoelectric vibration plate 23, and the first sealing member 27 and the second sealing member 28 that close the opening of the piezoelectric vibration plate 23. The oscillator 22 has an internal space S formed by the frame portion 24 of the piezoelectric vibration plate 23, the first sealing member 27, and the second sealing member 28. The oscillator 22 includes the vibrating portion 25 arranged in the internal space S. An inert gas, such as nitrogen gas, is sealed within the internal space S. The oscillator 22 oscillates at a predetermined frequency in response to a voltage applied from each of the oscillator mounting terminals 24d.

As illustrated in FIG. 11, the integrated circuit element 30 is an IC that controls the oscillator 22. The configuration of the integrated circuit element 30 is the same as that of the integrated circuit element 10 in the first embodiment, and therefore, description thereof will be omitted.

The substrate 31 is a single-layer resin substrate that electrically connects the oscillator 22 and the integrated circuit element 30 to each other via a wiring pattern (not illustrated) and forms the oscillator 22 and the integrated circuit element 30 as an integrated body. The substrate 31 includes, as a base material, for example, one of glass epoxy resin, polyimide resin, or fluoropolymer resin, which is an insulator that can be easily processed by cutting or the like. The substrate 31 enables the piezoelectric vibration device 21 to be easily configured in an arbitrary shape. The substrate 31 is a rectangular plate material.

As illustrated in FIG. 13, one of principal surfaces of the substrate 31 is formed as a first mounting surface 31a including the wiring pattern that includes a pad, a land, or the like formed of a conductor, such as copper. The oscillator 22 and the integrated circuit element 30 are each mounted on the first mounting surface 31a (see FIG. 11). Each of both the oscillator mounting terminals 24d (see FIG. 12) of the oscillator 2 is electrically connected to corresponding one of two connection terminals 31d on the first mounting surface 31a by a conductive bonding material. The oscillator 2 is arranged such that the second sealing member 28 faces the first mounting surface 31a. The second sealing member 28 is in contact with the first mounting surface 31a. Similarly, each integrated circuit element mounting terminal 30a of the integrated circuit element 30 is electrically connected to the wiring pattern of the first mounting surface 31a of the substrate 31 by a conductive bonding material.

Aa illustrated in FIG. 14, the other one of the principal surfaces of the substrate 31 that is in parallel to the one of the principal surfaces is configured as a second mounting surface 31b including external connection terminals 31f provided for mounting the substrate 31 on an external substrate. The external connection terminals 31f are each a plate-shaped terminal formed of conductive metal. The wiring pattern of the first mounting surface 31a is electrically connected to the external connection terminals 31f via internal wirings 31c.

As illustrated in FIGS. 11 and 12, the oscillator 22 mounted on the substrate 31 is electrically connected to the external substrate from the oscillator mounting terminals 24d via the connection terminals 31d on the first mounting surface 31a, the internal wirings 31c, and the external connection terminals 31f of the second mounting surface 31b (see FIG. 11). The vibrating portion 25 of the oscillator 22 is held in a cantilever-supported state on the frame portion 24 of the piezoelectric vibration plate 23 by the connecting portion 26. Thus, the vibrating portion 25 oscillates at a predetermined frequency in response to a voltage applied from the external substrate.

A molding portion, which is not illustrated, protects the substrate 31 and at least the oscillator 22 of the oscillator 22 and the integrated circuit element 30 mounted on the substrate 31. The molding portion is similar to the molding portion 12 in the first embodiment, and therefore, description thereof will be omitted.

With reference to FIG. 13, the first mounting surface 31a of the substrate 31 and the connection terminals 31d will now be described.

As illustrated in FIG. 13, the two connection terminals 31d are arranged on the first mounting surface 31a. Each of the connection terminals 31d is a plate-shaped terminal formed of conductive metal. A principal surface of each of the two connection terminals 31d (hereinafter simply referred to as the “connection terminals 31d”) is configured as a bonding surface 31e bonded to a corresponding one of the two oscillator mounting terminals 24d (see FIG. 12) of the oscillator 22. The bonding surface 31e is not covered by an insulating base material of the substrate 31 and is exposed.

The internal wirings 31c are connected to the connection terminals 31d. The internal wirings 31c are formed of conductive metal. The internal wirings 31c electrically connect the wiring pattern on the first mounting surface 31a to the external connection terminals 31f (see FIG. 14). An internal wiring 31c is connected to a corresponding one of the connection terminals 31d.

With reference to FIG. 14, the second mounting surface 31b and the external connection terminals 31f of the substrate 31 will now be described. FIG. 14 s a plan view of the second mounting surface 31b of the substrate 31 in the piezoelectric vibration device 21. In this embodiment, the second mounting surface 31b includes four external connection terminals 31f.

Aa illustrated in FIG. 14, the second mounting surface 31b is the other one of the principal surfaces of the substrate 31 and is electrically connected to the external substrate. The second mounting surface 31b of the substrate 31 includes four recessed portions 31g corresponding to the four external connection terminals 31f. The second mounting surface 31b and the external connection terminals 31f are similar to the second mounting surface 11b and the external connection terminals 11g in the first embodiment, and therefore, description thereof will be omitted.

With reference to FIGS. 13 to 15, an inspection terminal 31h of the substrate 31 will now be described.

As illustrated in FIG. 13, the inspection terminal 31h is used to measure the characteristics of the oscillator 22 mounted on the first mounting surface 31a of the substrate 31. The piezoelectric vibration device 21 is provided with a pair of inspection terminals 31h, each corresponding to one of the two electrodes of the oscillator 22. In the following embodiment, the inspection terminals 31h refer to the pair of inspection terminals 31h unless otherwise described. The configuration of the inspection terminals 31h is similar to that of the inspection terminals 11k in the first embodiment, and therefore, description thereof will be omitted.

The inspection terminals 31h are arranged in positions that do not overlap with the connection terminals 31d, which are pads on which the oscillator 22 is mounted, when viewed in the direction perpendicular to the first mounting surface 31a. That is, the inspection terminals 31h are not directly connected to the connection terminals 31d. In addition, each of conductors 31k electrically connected to a corresponding one of the inspection terminals 31h has an end portion on the first mounting surface 31a side, which is not directly connected to a connection terminal 31d.

As illustrated in FIG. 14, the inspection terminals 31h are arranged in positions that do not overlap with the external connection terminals 31f, when viewed in the direction perpendicular to the first mounting surface 31a. That is, the inspection terminals 31h are not directly connected to the external connection terminals 31f. Each of the inspection terminals 31h is electrically connected to an end portion of a conductor 31k, located on the second mounting surface 31b side, within a corresponding through-hole, wherein the conductor 31k covers at least the inner surface of the through-hole extending through the substrate 31 from the first mounting surface 31a side toward the second mounting surface 31b side. Naturally, the conductors 31k electrically connected to the inspection terminals 31h are not directly connected to the connection terminals 31d or the external connection terminals 31f.

As illustrated in FIG. 15, each of the conductors 31k, to which a corresponding one of the pair of inspection terminals 31h is electrically connected, has an end portion on the first mounting surface 31a side, which is electrically connected to one end of a different internal wiring 31j. The other ends of the internal wirings 31j are each electrically connected to a corresponding connection terminal 31d. That is, each of the pair of inspection terminals 31h is electrically connected to a corresponding connection terminal 31d via a corresponding conductor 31k and internal wiring 31j.

The inspection terminals 31h are not electrically connected to the external connection terminals 31f, or the internal wirings or the like. That is, the inspection terminals 31h are electrically connected to corresponding connection terminals 31d on the second mounting surface 31b side without going through the external connection terminals 31f on the second mounting surface 31b side. End portions of the inspection terminals 31h on the second mounting surface 31b side and the internal wirings 31c are covered with insulating resin. On the second mounting surface 31b, at least the inspection terminals 31h are covered with an insulating resin.

The inspection terminals 31h are electrically connected to the oscillator 2 via the conductors 31k, the internal wirings 31j and the connection terminals 31d. The inspection terminals 31h are located on the second mounting surface 31b side that is not sealed with the molding portion 12. Therefore, the inspection terminals 31h can be electrically connected to the oscillator 2 sealed with the molding portion 12, via their end portions on the second mounting surface 31b side.

### Other Embodiments

In the above-described embodiments, each of the substrates 11 and 31 includes the recessed portion 11j or 31g for each of the external connection terminals 11g or 31f. Alternatively, the substrates may not include a recessed portion for each external connection terminal. In the substrates, a plurality of external connection terminals may be arranged in a single recessed portion.

In the above-described embodiments, the piezoelectric vibration device 1 includes the oscillator 2 having a three-layer structure in which the piezoelectric vibration plate 3, the first sealing member 6, and the second sealing member 8 are laminated. Alternatively, the piezoelectric vibration device may include an oscillator having a structure of more than three layers. The oscillator may be a four-layer oscillator in which a sensor, such as a thermistor, is further mounted on the principal surface of the first sealing member.

In the above-described embodiments, each of the piezoelectric vibration devices 1 and 21 is formed of the single-layer substrate 11 or 31. Alternatively, the piezoelectric vibration devices may be formed of a laminated substrate having a plurality of layers.

In the above-described embodiments, each of the inspection terminals 11k and 31h includes a land. Alternatively, the inspection terminals may not include a land.

In the above-described embodiments, each of the inspection terminals 11k and 31h is located substantially in the same plane as the second mounting surface 11b or 31b. Alternatively, the inspection terminals may be positioned below the second mounting surface, toward the first mounting surface side. That is, the inspection terminals may be recessed relative to the second mounting surface. The inspection terminals may protrude beyond the second mounting surface.

In the above-described embodiments, each of the piezoelectric vibration devices 1 and 21 is configured such that the oscillator 2 or 22 and the integrated circuit element 10 or 30 are sealed with the molding portion 12. Alternatively, in each of the piezoelectric vibration devices, the oscillator and the integrated circuit element may not be mold-sealed. Each of the piezoelectric vibration devices may be configured such that the oscillator and the integrated circuit element are housed in an enclosure.

In the above-described embodiments, the inspection terminals 11k and 31h are covered with an insulating resin. Alternatively the inspection terminals may not be covered with the insulating resin.

In the above-described embodiments, the inspection terminals 11k and 31h, which are covered with the insulating resin, are configured to be visible from the outside. Alternatively, the inspection terminals covered with the insulating resin may not be visible from the outside. Each of the piezoelectric vibration devices may include a marker or the like that enables the position of the inspection terminal to be identified.

The embodiments of the present invention have been described above, but the above-described embodiments are merely illustrative examples for carrying out the present invention. Therefore, the present invention is not limited to the above-described embodiments and the above-described embodiments can be appropriately modified and implemented without departing from the gist of the present invention.

### REFERENCE SIGNS LIST

1, 21 piezoelectric vibration device
2, 22 oscillator
3, 23 piezoelectric vibration plate
4, 25 vibrating portion
4a, 25a excitation electrode
4b notch portion
5 bonding material
26 connecting portion
6, 27 first sealing member
7, 28 second sealing member
24 frame portion
24c through-hole
10, 30 integrated circuit element
10a, 30a integrated circuit element mounting terminal
10b wire
11, 31 substrate
11a, 31a first mounting surface
11b, 31b second mounting surface
11c, 11m, 31c, 31j internal wiring
11d, 31d connection terminal
11g, 31f external connection terminal
11e, 11h, 24a, 31e bonding surface
11f, 11j, 31g recessed portion
11k, 31h inspection terminal
11n, 31k conductor
11o insulating area
11p wire connection terminal
12 molding portion
33 bonding material
7a, 24d oscillator mounting terminal
S internal space

1. A piezoelectric vibration device, comprising:
at least a piezoelectric oscillator;
a resin molding portion that protects at least the piezoelectric oscillator; and
a resin substrate including a component mounting surface on one of its principal surfaces and a mounting surface on another one of the principal surfaces that is in parallel with the one of the principal surfaces, the component mounting surface including a wiring pattern that includes a plurality of pads, the mounting surface including a plurality of external connection terminals that are connected to the wiring pattern and to an external substrate,
at least the piezoelectric oscillator being mounted on the component mounting surface while being connected to the plurality of pads, at least a part of the component mounting surface being covered with the resin molding portion to include at least the piezoelectric oscillator,
wherein
the resin substrate includes, on the mounting surface side, an inspection terminal electrically connected to one of the pads on which the piezoelectric oscillator is mounted, without going through the external connection terminals.

2. The piezoelectric vibration device according to claim 1, wherein the inspection terminal is arranged in a position that does not overlap with the pads on which the piezoelectric oscillator is mounted or the plurality of the external connection terminals, when viewed in a direction perpendicular to the mounting surface.

3. The piezoelectric vibration device according to claim 1, wherein the resin substrate is formed of one of glass epoxy resin, polyimide resin, or fluoropolymer resin.

4. The piezoelectric vibration device according to claim 1, wherein the inspection terminal is electrically connected to a conductor filled in a through-hole penetrating the resin substrate in a thickness direction thereof, and the conductor is electrically connected to the piezoelectric oscillator.

5. The piezoelectric vibration device according to claim 1, wherein at least the inspection terminal is covered with an insulating resin.

6. The piezoelectric vibration device according to claim 5, wherein the resin substrate is configured such that at least a part of the mounting surface is covered with the insulating resin.
